(19) United States
(12) Patent Application Publication
(10) Pub. No.: US 2026/0003381 A1
(43) Pub. Date: Jan. 1, 2026

(54) MULTIPLE INPUT LINEAR VOLTAGE REGULATOR

(71) Applicant: INTERNATIONAL BUSINESS MACHINES CORPORATION, ARMONK, NY (US)

(72) Inventors: WILLIAM V. HUOTT, HOLMES, NY (US); LUKE L. JENKINS, POUGHKEEPSIE, NY (US); MICHAEL SPERLING, POUGHKEEPSIE, NY (US)

(21) Appl. No.: 18/754,713

(22) Filed: Jun. 26, 2024

(51) Int. Cl. G05F 1/59; G06F 1/26; H01L 23/535; H01L 25/18; H10B 80/00

(52) U.S. Cl. CPC G05F 1/59; G06F 1/26; H01L 23/535; H01L 25/18; H10B 80/00

(57) ABSTRACT

A multiple input linear voltage regulator includes an output port configured to supply an output voltage to one or more processor components; a first regulating transistor operable to receive a first input voltage from a first supply and provide a first regulated voltage range to the output port; a second regulating transistor operable to receive a second input voltage from a second supply and provide a second regulated voltage range to the output port, wherein the first input voltage is different from the second input voltage; and a control circuit operable to selectively drive the first regulating transistor and the second regulating transistor based on at least a target output voltage.

### BACKGROUND

The present disclosure relates to methods, apparatus, and products for a multiple input linear voltage regulator. Voltage regulators are tasked with regulating the power supply to computer processors and are critical to their functionality. Too much voltage can lead to substantial power inefficiency, while too little voltage can lead to processor failure. The size, efficiency, and scalability of voltage regulators are significant factors in designing and implementing modern computer processors.

### SUMMARY

According to embodiments of the present disclosure, various methods, apparatuses, and products for a multiple input linear voltage regulator are described herein. In some aspects, a multiple input linear voltage regulator includes an output port configured to supply an output voltage to one or more processor components. The multiple input linear voltage regulator also includes a first regulating transistor operable to receive a first input voltage from a first supply and provide a first regulated voltage to the output port. The multiple input linear voltage regulator also includes a second regulating transistor operable to receive a second input voltage from a second supply and provide a second regulated voltage to the output port, where the first input voltage is different from the second input voltage. The multiple input linear voltage regulator further includes a control circuit operable to selectively drive the first regulating transistor and the second regulating transistor based on a target output voltage.

### BRIEF DESCRIPTION OF THE DRAWINGS

FIG. 1 sets forth an example multiple input linear voltage regulator in accordance with at least one embodiment of the present disclosure.

FIG. 2 sets forth another example multiple input linear voltage regulator in accordance with at least one embodiment of the present disclosure.

FIG. 3 sets forth an example processor for a multiple input linear voltage regulator in accordance with at least one embodiment of the present disclosure.

FIG. 4 sets forth another example processor for a multiple input linear voltage regulator in accordance with at least one embodiment of the present disclosure.

FIG. 5 sets forth another example processor for a multiple input linear voltage regulator in accordance with at least one embodiment of the present disclosure.

FIG. 6 sets forth another example processor for a multiple input linear voltage regulator in accordance with at least one embodiment of the present disclosure.

FIG. 7 sets forth a flow chart of an example method for a multiple input linear voltage regulator in accordance with at least one embodiment of the present disclosure.

FIG. 8 sets forth a flow chart of an example method for a multiple input linear voltage regulator in accordance with at least one embodiment of the present disclosure.

FIG. 9 sets forth a flow chart of an example method for a multiple input linear voltage regulator in accordance with at least one embodiment of the present disclosure.

FIG. 10 sets forth a flow chart of an example method for a multiple input linear voltage regulator in accordance with at least one embodiment of the present disclosure.

FIG. 11 sets forth an example computing environment for a multiple input linear voltage regulator.

### DETAILED DESCRIPTION

Processors require a certain voltage (i.e., an ideal or desired voltage) that is the minimum voltage for the processor to maintain the processor frequency and function properly. This voltage is referred to herein as the target voltage. In processors that use dynamic frequency scaling and power saving, the frequency of the processor varies and therefore the target voltage may vary over time. Even in processors that use a fixed frequency, the target voltage required by the processor can vary depending on the workload on the processor. A voltage supply to the processor that is below the target voltage can result in the inability to maintain processor frequency, require throttling, or even result in processor faults or error. This can lead to failures in program execution. However, a voltage supply to the processor that is in excess of the target voltage wastes power, resulting in an inefficient system, create excess heat, and can reduce the lifespan of the processor chip itself. Accordingly, voltage regulators convert, or step down, a power supply voltage to the target voltage with the aim of not exceeding the target voltage in order to provide the processor with the power needed to function properly in the most efficient manner.

Due to silicon process tolerances, every processor requires a slightly different voltage to operate most efficiently. Further, there can be differences in ideal voltage from one chiplet or processor core to another in the same processor due to variations process tolerances and different workloads. Within a processor, one core may be idle while another core is under a heavy workload. Variations in ideal voltage due to fabrication and variations across cores due to different workloads usually require many different voltage domains feeding the processor.

Once type of voltage regulator that can be used for a processor is a switching regulator, such as a buck converter, switched capacitor, or others. Switching regulators can be very efficient, especially at high load currents, resulting in little wasted power. However, for many applications, switching regulators consume too much space to place them on the processor die itself, or close to the processor die such as within an interposer on which the die is mounted. Further, switching noise associated with switching regulators can make them unsuitable for placement too close to the processor die, requiring significant capacitance which requires additional space or higher switching frequency which reduces efficiency. Heat dissipation also poses thermal challenges. As such, switching regulators are typically placed adjacent to the processor die on a substrate. However, it is advantageous to place the voltage regulator as close to the processor die as possible to provide a fast response to dynamic changes in power demand.

Another type of voltage regulator that could be used for processors is a linear voltage regulator. Advantageously, linear voltage regulators are much simpler to design and can be made much smaller than switching regulators, thus permitting placement of the linear voltage regulator closer to the processor die, or even on the die itself, to provide a fast response to dynamic changes in power demand. Linear voltage regulators function by using an active pass transistor that operates in its linear region to drop excess voltage from the input to the output. Linear voltage regulators dissipate the excess power from the step-down voltage as heat, which makes them less efficient than switching regulators. The dropout voltage of the pass transistor is the minimum difference between the input and output voltage at which the regulator can still regulate properly. Low dropout (LDO) regulators are designed to operate with a small difference between the input and output voltage to improve efficiency. However, the limited range where LDO linear voltage regulators operate efficiently can make them unsuitable to provide the range of target voltages required by the processor.

To illustrate the inefficiency of linear voltage regulators, consider a processor whose range of target voltages is 100 millivolts. That is, as simplified example, consider that the input voltage to the linear voltage regulator is 1 Volt, but the processor at various times may demand a voltage anywhere from 900 millivolts to 1 Volt. When the processor demands 905 millivolts, the dropped voltage is 95 millivolts, making the linear voltage regulator just 90.5% efficient. The power associated with the 95 millivolts is dissipated as heat.

Embodiments in accordance with the present disclosure provide a multiple input linear voltage regulator in which multiple supplies of different input voltages are regulated by respective pass transistors and supply a common output to the processor, thus narrowing the voltage range each pass transistor needs to support and enabling the multiple input linear voltage regulator to support high currents without excessive power loss and heat dissipation. While the multiple input linear voltage regulator is small enough to place on-die, it is also small enough to place within the processor interposer adjacent to the power supply path. This design maximizes power efficiency (equal to or better than a buck regulator), minimizes area consumed by the regulators, and the pass transistor of the linear regulator also can act as an off switch to completely disable a core to improve sustainability at idle and low core utilization. In addition, a more local voltage regulation provides tighter voltage control than external point of load.

In the multiple input linear voltage regulator, each of the multiple pass transistors regulates a different input voltage and supplies its regulated voltage to a common output port. Thus, each pass transistor is responsible for supplying a corresponding range of the distribution of target voltages used by the processor. A controller adjusts the pass transistors and switches between them seamlessly. For example, in a two-input linear voltage regulator, one pass transistor regulating the higher input voltage supplies the high-voltage half of the processor distribution, while the other pass transistor regulating the lower input voltage supplies the lower voltage half of the process distribution. A processor can utilize the higher voltage range at high workloads to optimize performance and switch to the lower voltage range to optimize energy efficiency and sustainability. The multiple input linear voltage regulator is scalable to any number of input voltages and voltage distribution partitions, each input voltage containing its own pass transistor, where the control logic can optimize which input voltage or what combination of input voltages to be utilized at any given time.

The multiple input linear voltage regulator saves size compared to switching regulators on processers and can be more efficiently implemented in this way. Linear regulators can be faster, quieter, and smaller than switching regulators, and they require no output inductor, which tend to be physically large, and need less output capacitance. Therefore, this design results in further area conservation. The multiple input linear voltage regulator keeps each pass transistor creating a Vₒᵤₜ (Output Voltage) that is never too far from one of the input voltages for optimal efficiency and minimal heat dissipation. The various input voltages can be constantly and dynamically tuned in system based on voltage needs of any given processor drawer.

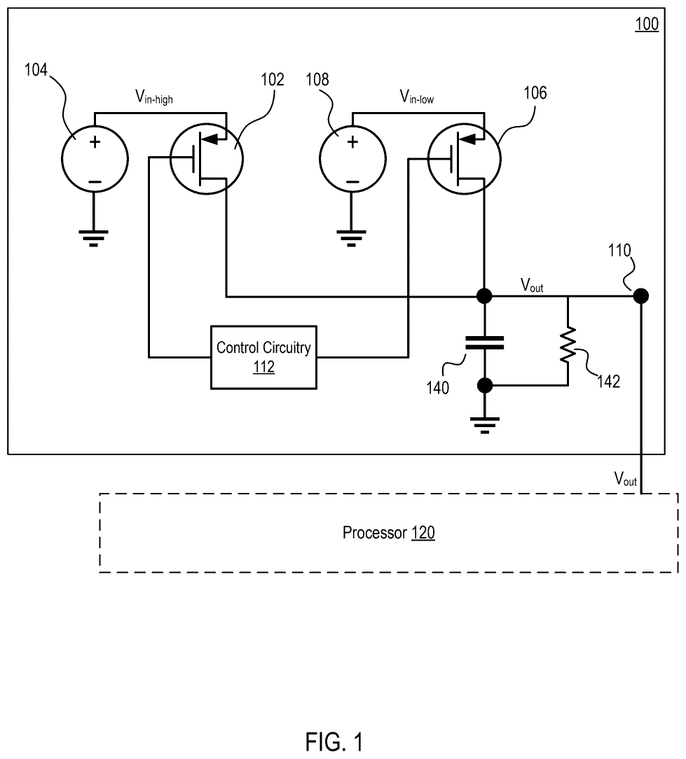

For further explanation, FIG. 1 sets forth a diagram of an example multiple input linear voltage regulator 100 in accordance with at least one embodiment of the present disclosure. The multiple input linear voltage regulator 100 includes a first pass transistor 102 that receives a first input voltage from a first voltage supply 104 and a second pass transistor 106 that receives second input voltage from a second voltage supply 108, where the first input voltage and the second input voltage are different. The first pass transistor 102 and the second pass transistor 106 are connected to a common output port 110 that supplies a Vₒᵤₜ voltage to a processor 120. For ease of explanation and not limitation, consider that the first input voltage is higher than the second input voltage, and thus the first input voltage is referred to as V_{in-high} and the second input voltage is referred to as V_{in-low}. For a distribution of processor target voltages ranging from M millivolts to N millivolts, the first pass transistor 102 regulates V_{in-high} to supply Vₒᵤₜ voltages in the range of M to (M−N)/2 (i.e., the high voltage range) and the second pass transistor 106 regulates V_{in-low} to supply Vₒᵤₜ voltages in the range of (M−N)/2 to N (i.e., the low voltage range). In some examples, a load capacitor 140 and a load resistor 142 are coupled in parallel to ground and Vₒᵤₜ for voltage smoothing.

In some examples, the first pass transistor 102 and the second pass transistor 106 are metal-oxide-semiconductor field-effect transistors (MOSFETs), although it will be appreciated that other types of transistors may be employed to achieve the same effect. For case of explanation, consider that the first pass transistor 102 and the second pass transistor 106 are P-type MOSFETs. As such, the first voltage supply 104 is connected to the source terminal of the first pass transistor 102 and the drain terminal of the first pass transistor 102 is connected to the output port 110. The gate terminal of the first pass transistor 102 is driven by control circuitry 112. Likewise, the second voltage supply 108 is connected to the source terminal of the second pass transistor 106 and the drain terminal of the second pass transistor 106 is connected to the output port 110. The gate terminal of the second pass transistor 106 is driven by another output of control circuitry 112. When either pass transistor is turned on, and a channel has been created that allows current between the source and the drain, the MOSFET operates like a resistor controlled by the gate voltage relative to both the source and drain voltages.

In some examples, the control circuitry adjusts the first pass transistor 102 or the second pass transistor 106 to meet a target voltage required by the processor 120 or processor component (e.g., a processor core). For example, the target voltage may be communicated to control circuitry 112 by a power management controller of the processor 120. The control circuitry 112 operates either the first pass transistor 102 or the second pass transistor 106, depending on whether the target voltage is with the high voltage range or the low voltage range, by applying a voltage to the gate of that transistor. For example, when the target voltage is in the high voltage range, the first pass transistor 102 is operated to provide the regulated voltage to Vₒᵤₜ, while the second pass transistor 106 remains off. When the target voltage is in the low voltage range, the second pass transistor 106 is operated to provide the regulated voltage to Vₒᵤₜ, while the first pass transistor 102 remains off. In some examples, the control circuitry 112 selects which of the first pass transistor 102 and second pass transistor 106 will provide Vₒᵤₜ by comparing the target voltage to the input voltage that is supplied to the second pass transistor 106 (i.e., V_{in-low}). If the target voltage is at or below this input voltage, the second pass transistor 106 can be used to provide Vₒᵤₜ and should be used to optimize efficiency. If the target voltage is above this input voltage, the first pass transistor 102 must be used to supply Vₒᵤₜ. In this way, the voltage drop across the pass transistor is minimized and the efficiency of the multiple input linear voltage regulator 100 is increased by dissipating less power as heat.

In some examples, the control circuitry 112 operates the pass transistors to regulate the input voltages by comparing Vₒᵤₜ to the target voltage. If the target voltage is greater than Vₒᵤₜ, the control circuitry 112 decreases (in the case of a p-type MOSFET) the gate voltage of the pass transistor to increase the current supplied from the Vᵢₙ connected to the drain of the pass transistor. If the target voltage is less than Vₒᵤₜ, the control circuitry 112 increases the gate voltage to restrict the current supplied by the pass transistor. In operating the second pass transistor 106, when the second pass transistor 106 reaches the maximum voltage it can supply (when Vₒᵤₜ=V_{in-low}), the control circuitry 112 controls the transition from the second pass transistor 106 to the first pass transistor 102. Similarly, in operating the first pass transistor 102, the target voltage falls to the at or below the input voltage of the second pass transistor 106 (V_{in-low}), the control circuitry 112 controls the transition from the first pass transistor 102 to the second pass transistor 106. In some implementations, when the target voltage transitions between the high voltage range and the low voltage range, the transition can be handled by the control circuitry 112 simply turning off one pass transistor and turning on the other. Voltage ripple supplied to the processor component can be mitigated with sufficient capacitance at the point of load. In other implementations, both the first pass transistor 102 and the second pass transistor 106 are briefly operated concurrently during the transition from one pass transistor to the other. For example, both the first pass transistor 102 and the second pass transistor 106 may be operated concurrently until Vₒᵤₜ is a threshold amount above or below V_{in-low}. This threshold amount of voltage above and below V_{in-low} is a boundary range in which both the first pass transistor 102 and the second pass transistor 106 are operated concurrently. For example, the boundary may be defined by ±10 millivolts with respect to V_{in-low}.

Consider an example in which the second pass transistor 106 is providing Vₒᵤₜ and the target voltage is being increased due to increasing workload on the processor 120. As Vₒᵤₜ upward approaches V_{in-low}, or as the gate voltage of the second pass transistor 106 approaches zero, the control circuitry 112 detects this boundary condition and turns on the first pass transistor 102 while also keeping the second pass transistor 106 on. Once Vₒᵤₜ has increased past the boundary condition, the control circuitry 112 turns off the second pass transistor 106. Consider another example in which the first pass transistor 102 is providing Vₒᵤₜ and the target voltage is being decreased due to decreasing workload on the processor 120. As Vₒᵤₜ downward approaches V_{in-low}, the control circuitry 112 detects this boundary condition and turns on the second pass transistor 106 while also keeping the first pass transistor 102 on. Once Vₒᵤₜ has decreased past the boundary condition, the control circuitry 112 turns off the first pass transistor 102. In this way, the control circuitry 112 seamlessly switches between the two pass transistors as the supply of Vₒᵤₜ, thus avoiding a voltage ripple that could disrupt processor functionality.

In some cases, a transient load spike may trigger and sudden increase in power demand within the processor. In such cases, the control circuitry 112 is configured to detect these spikes and respond by operating both the first pass transistor 102 and the second pass transistor 106 concurrently. In some implementations, the control circuitry 112 detects when the difference between Vₒᵤₜ and the target voltage is a greater than a threshold amount, e.g., due to a load spike. To quickly address the sudden power demand, the control circuitry 112 operates both the first pass transistor 102 and the second pass transistor 106 to supply voltage at Vₒᵤₜ. When the processor returns to a steady state, one of the pass transistors is turned off for efficient operation. In this way, both voltage supplies 104, 108 are utilized to respond to transient conditions, thus ensuring proper functioning of the processor 120.

Although the above example is provided in the context of p-type MOSFETs, it will be appreciated the design of the multiple input linear voltage regulator 100 is readily adapted to use n-type MOSFETs as well as other types of transistors.

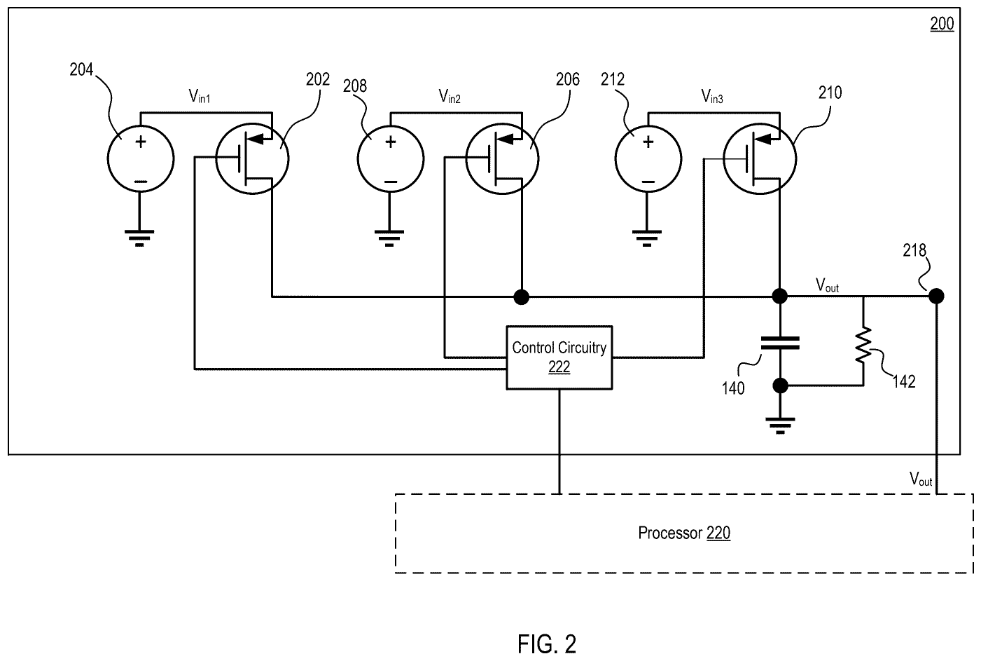

For further explanation, FIG. 2 sets forth a diagram of another example multiple input linear voltage regulator 200 in accordance with at least one embodiment of the present disclosure. The multiple input linear voltage regulator 200 of FIG. 2 demonstrates the scalability of a multiple input linear voltage regulator in accordance with the present disclosures. The multiple input linear voltage regulator 200 is substantially similar to the multiple input linear voltage regulator 100 of FIG. 1 except that three input voltages are supplied to the multiple input linear voltage regulator 200. Although three are used in this example, a multiple input linear voltage regulator can be configured to use any number of input voltages. To that end, the multiple input linear voltage regulator 200 receives input voltages Vᵢₙ₁, Vᵢₙ₂, Vᵢₙ₃ from voltage supplies 204, 208, 212, where Vᵢₙ₁ is a higher voltage than Vᵢₙ₂ and Vᵢₙ₂ is a higher voltage than Vᵢₙ₃. Accordingly, in a particular example, pass transistor 202 supplies a regulated output voltage in a first range of target voltages between ˜Vᵢₙ₃ and ˜Vᵢₙ₂; pass transistor 206 supplies a regulated output voltage in a second range of target voltages between ˜Vᵢₙ₂ and ˜Vᵢₙ₁; and pass transistor 210 supplies a regulated output voltage in a third range of target voltages between. ˜Vᵢₙ₁ and the lowest voltage in the distribution of processor voltages. Thus, by way of example and not limitation, if the distribution of processor voltages spans 150 millivolts, each pass transistor 202, 206, 210 supplies a regulated output voltage within a respective 50 millivolt range.

In the example of FIG. 2, pass transistor 202 receives Vᵢₙ₁ and supplies a regulated output voltage to a common output port 218. Control circuitry 222 controls a gate voltage of pass transistor 202 to regulate the output voltage within the transistor's linear range, as discussed above. Similarly, pass transistor 206 receives Vᵢₙ₂ and supplies a regulated output voltage to the common output port 218. Control circuitry 222 controls a gate voltage of pass transistor 206 to regulate the output voltage. Likewise, pass transistor 210 receives Vᵢₙ₃ and supplies a regulated output voltage to a common output port 218. Control circuitry 222 controls a gate voltage of pass transistor 210 to regulate the output voltage. The common output port 218 supplies Vₒᵤₜ to a processor 220. The control circuitry selectively drives the gate of a particular pass transistor, based on the target voltage, to provide Vₒᵤₜ and drives the gate of the other pass transistors to keep them turned off. In some examples, a load capacitor 140 and a load resistor 142 are coupled in parallel to ground and Vₒᵤₜ for voltage smoothing.

The transitioning of the target voltage from one voltage range to another can be carried out in the same manner as described above with reference to FIG. 1. For example, as the target voltage enters a boundary area respective of Vᵢₙ₃, the control circuitry can operate pass transistor 210 and pass transistor 206 concurrently, such that there is no transient disruption to Vₒᵤₜ as the supply to Vₒᵤₜ switches between pass transistor 210 and pass transistor 206. Similarly, in some examples, as the target voltage enters a boundary area respective of Vᵢₙ₂, the control circuitry can operate pass transistor 206 and pass transistor 202 concurrently, such that there is no transient disruption to Vₒᵤₜ as the supply to Vₒᵤₜ switches between pass transistor 206 and pass transistor 202. In alternative examples, a capacitor can be used to buffer Vₒᵤₜ as one pass transistor is turned off prior to another pass transistor being turned on.

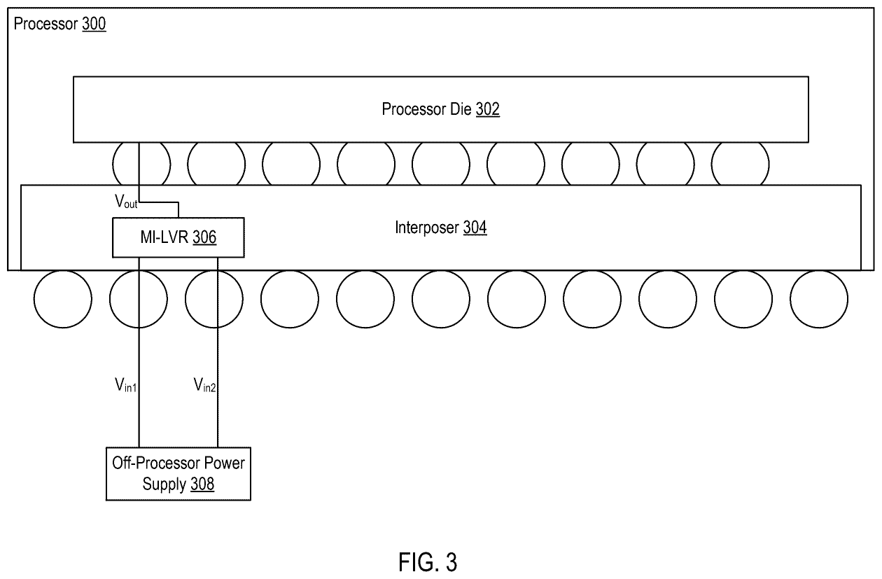

For further explanation, FIG. 3 sets forth a block diagram of an example processor 300 including a multiple input linear voltage regulator 306. The example processor 300 includes a processor die 302 mounted on an interposer 304. A multiple input linear voltage regulator 306 is fabricated within the interposer 304. For example, the multiple input linear voltage regulator 306 can be the multiple input linear voltage regulator 100 of FIG. 2 or the multiple input linear voltage regulator 200 of FIG. 2. The multiple input linear voltage regulator 306 receives two or more different input voltages Vᵢₙ₁, Vᵢₙ₂ from an off-processor power supply 308 via the interposer 304 and regulates the multiple input voltages as discussed above to provide a single Vₒᵤₜ supply at the processor die 302. In this manner, the multiple input linear voltage regulator 306 is located close to the processor die 302 and close to the power supply lines coming into the interposer 304, thus enabling the multiple input linear voltage regulator 306 to provide a fast response to voltage demands of the processor 300 without consuming any space on the processor die 302.

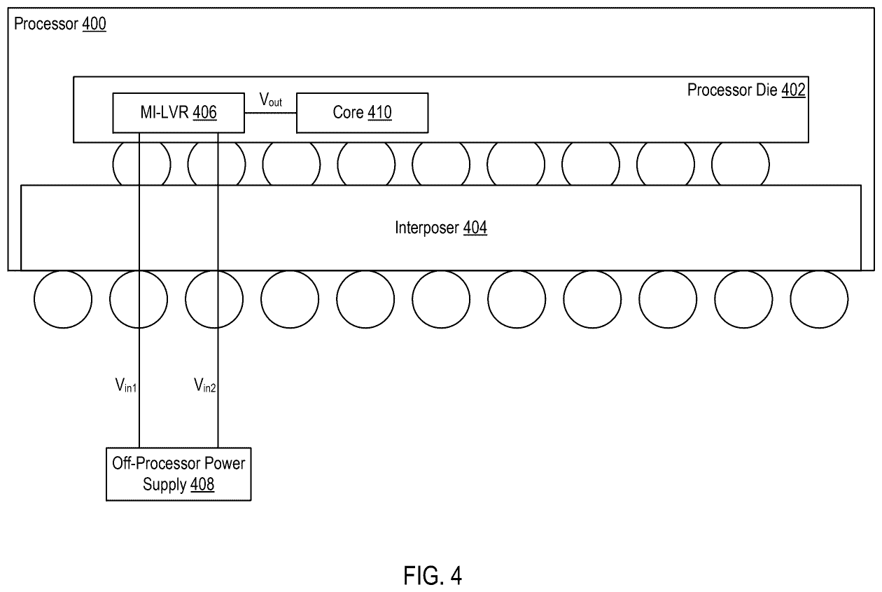

For further explanation, FIG. 4 sets forth a block diagram of an example processor 400 including a multiple input linear voltage regulator 406. The example processor 400 includes a processor die 402 mounted on an interposer 404. A multiple input linear voltage regulator 406 is fabricated on the processor die 402. For example, the multiple input linear voltage regulator 406 can be the multiple input linear voltage regulator 100 of FIG. 2 or the multiple input linear voltage regulator 200 of FIG. 2. The multiple input linear voltage regular 406 receives two or more different input voltages Vᵢₙ₁, Vᵢₙ₂ from an off-processor power supply 408 via the interposer 404 and regulates the multiple input voltages as discussed above to provide a single Vₒᵤₜ supply at the processor die 402, for example, to a processor core 410. In this manner, the multiple input linear voltage regulator 406 is located on the processor die 402 to provide a fast response to voltage demands of the processor 300. Although the multiple input linear voltage regulator 406 consumes space on the processor die 402, the multiple input linear voltage regulator 406 is more compact than a switching regulator and produces less heat and noise.

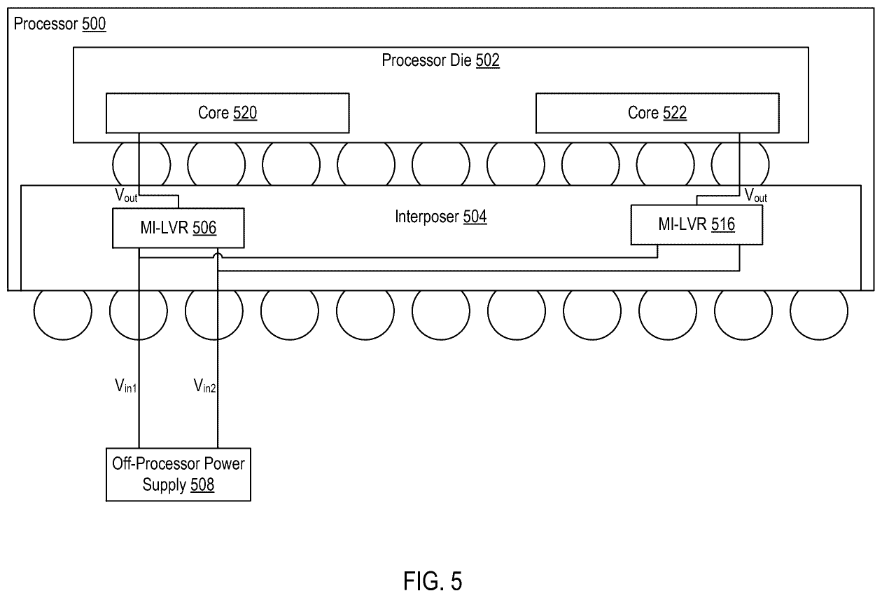

For further explanation, FIG. 5 sets forth a block diagram of an example processor 500 including two or more multiple input linear voltage regulators 506, 516. The example processor 500 includes a processor die 502 mounted on an interposer 504. The processor die 502 includes two or more processor cores 520, 522. A multiple input linear voltage regulator 506, 516 for each core 520, 522 is fabricated within the interposer 504. For example, the multiple input linear voltage regulators 506, 516 can be the multiple input linear voltage regulator 100 of FIG. 2 or the multiple input linear voltage regulator 200 of FIG. 2. The multiple input linear voltage regulators 506, 516 receives two or more different input voltages Vᵢₙ₁, Vᵢₙ₂ from an off-processor power supply 508. Multiple input linear voltage regulator 506 regulates the multiple input voltages as discussed above to provide a single Vₒᵤₜ supply to processor core 520, while multiple input linear voltage regulator 516 regulates the multiple input voltages as discussed above to provide a single Vₒᵤₜ supply to processor core 522. In addition to the advantages discussed above, providing a per-core voltage regulation using respective multiple input linear voltage regulators addresses the different power needs of the cores rather than running both cores at the same voltage. For example, one core may be under a heavy workload while the other core is idle, thus wasting energy. Further, the multiple input linear voltage regulator can be used to turn an idle core completely off, which further conserves energy. In alternative examples, the multiple input linear voltage regulator 506, 516 may be located on the processor die 502 as discussed above with reference to FIG. 4.

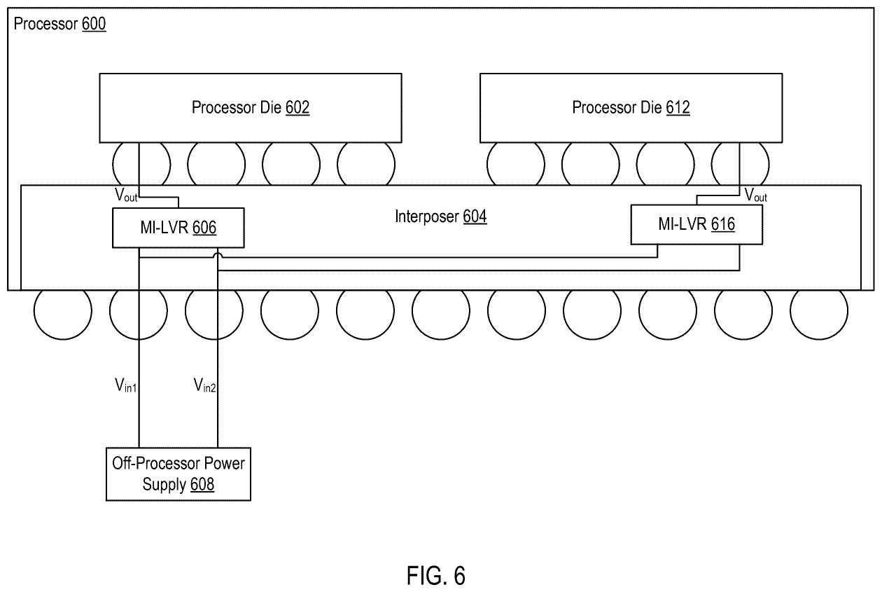

For further explanation, FIG. 6 sets forth a block diagram of an example processor 600 including two or more multiple input linear voltage regulators 606, 616. The example processor 600 includes two or more processor dies 602, 612 mounted on an interposer 604. A multiple input linear voltage regulator 606, 616 for each processor die 602, 612 is fabricated within the interposer 604. For example, the multiple input linear voltage regulators 606, 616 can be the multiple input linear voltage regulator 100 of FIG. 2 or the multiple input linear voltage regulator 200 of FIG. 2. The multiple input linear voltage regulators 606, 616 receives two or more different input voltages Vᵢₙ₁, Vᵢₙ₂ from an off-processor power supply 608. Multiple input linear voltage regulator 606 regulates the multiple input voltages as discussed above to provide a single Vₒᵤₜ supply to processor die 602, while multiple input linear voltage regulator 616 regulates the multiple input voltages as discussed above to provide a single Vₒᵤₜ supply to processor die 612. In addition to the advantages discussed above, providing a per-die voltage regulation using respective multiple input linear voltage regulators addresses the different power needs of the dies rather than running both dies at the same voltage. For example, due to process variations, each die may have different ranges of ideal voltages. In alternative examples, the multiple input linear voltage regulator 606, 616 may be respectively located on the processor dies 602, 612 as discussed above with reference to FIG. 4. Further, there may be a multiple linear voltage regulator for each core of each die, as discussed above with reference to FIG. 5. It will be appreciated that the various arrangements shown in FIG. 3 to FIG. 6 are combinable in accordance with principles of the present disclosure.

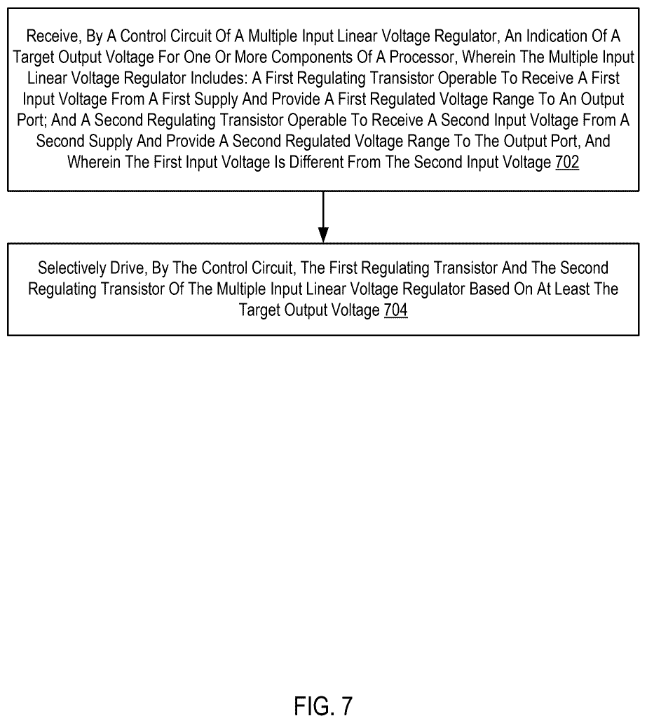

For further explanation, FIG. 7 sets forth a flow chart of an example method of a multiple input linear voltage regulator in accordance with at least one embodiment of the present disclosure. The method of FIG. 7 includes receiving 702, by a control circuit of a multiple input linear voltage regulator, an indication of a target output voltage for one or more components of a processor. The multiple input linear voltage regulator includes a first regulating transistor operable to receive a first input voltage from a first supply and provide a first regulated voltage to an output port. The multiple input linear voltage regulator also includes a second regulating transistor operable to receive a second input voltage from a second supply and provide a second regulated voltage to the output port, and wherein the first input voltage is different from the second input voltage. In various examples, the multiple input linear voltage regulator is any of the multiple input linear voltage regulator discussed above with reference to FIG. 1 to FIG. 6, or combinations thereof. As such, the regulating transistors may be MOSFET pass transistors that are operated in the linear range. In some examples, the control circuit of the multiple input linear voltage regulator receives 702 the indication of the target output voltage for one or more components of a processor by detecting a signal from the processor, a processor core, a processor die that is indicative of the voltage demand of that component. For example, the target voltage may be the ideal voltage of the component.

The method of FIG. 7 also includes selectively operating 704 a first regulating transistor and a second regulating transistor of the multiple input linear voltage regulator based on the target output voltage. In some examples, the control circuit selectively operates 704 the first regulating transistor and the second regulating transistor by applying a voltage to the gate of the first regulating transistor, the second regulating transistor, or both. In some examples, to supply the output voltage, the control circuitry favors the regulating transistor whose input voltage is the lowest input voltage that can be used to meet the target voltage. For example, where the first input voltage is lower than the second input voltage, if the first regulating transistor can provide a regulated supply that is equal to the target voltage, the first regulating transistor is selected to provide the output voltage. If the input voltage to the first regulating transistor is too low to provide a regulated supply that is equal to the target voltage, the second regulating transistor is selected to provide the output voltage. The regulating transistor that is not selected to provide the output voltage may be turned off. In some examples, both the first regulating transistor the second regulating transistor are selected to provide the output voltage based on the target voltage, as will be explained in greater detail below.

In this manner, a multiple input linear voltage regulator extends the operating range at which a linear voltage regulator can remain efficient. Thus, the multiple input linear voltage regulator in accordance with the present disclose provides practical and sustainable linear voltage regulation to processors. Because of its compact size compared to switching regulators, the design of the multiple input linear voltage regulator is amenable to providing a unique voltage domain at every core of the chip. Further, because of its case of implementation, design and fabrication costs are reduced.

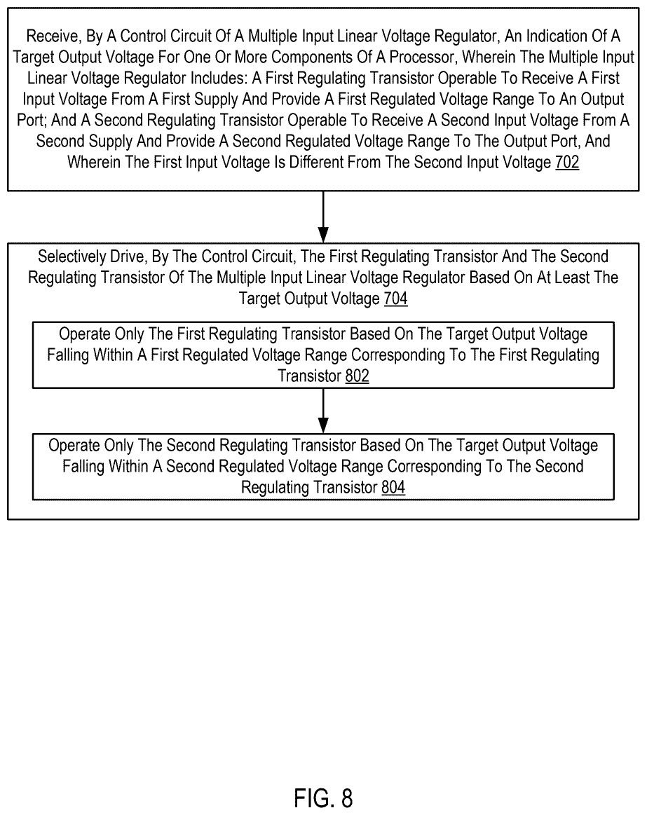

For further explanation, FIG. 8 sets forth a flow chart of another example method of a multiple input linear voltage regulator in accordance with at least one embodiment of the present disclosure. As explained above, the voltage demanded by a processor or processor component at any point in time varies based on processor conditions but falls within a particular range of voltages. This range of voltages is partitioned based on the maximum voltage each supply can provide and the number of input voltages available. In some examples, the input voltages are selected such that the range of voltages is evenly partitioned. Each regulating transistor is thus responsible for providing a regulated output voltage across a subrange in the range of voltages, where the upper limit of that subrange is the input voltage to the regulating transistor. Accordingly, in some examples, the control circuit selectively drives a first regulating transistor and a second regulating transistor of the multiple input linear voltage regulator based on the target output voltage by determining the subrange in which the target output voltage lies and controlling the regulating transistor corresponding to that subrange to provide the target output voltage.

Therefore, the method of FIG. 8 extends the method of FIG. 7 in that selectively operating 704 a first regulating transistor and a second regulating transistor of the multiple input linear voltage regulator based on the target output voltage includes operating 802 only the first regulating transistor based on the target output voltage falling within a first range corresponding to the first regulating transistor and operating 804 only the second regulating transistor based on the target output voltage falling within a second range corresponding to the second regulating transistor. For example, when the target input voltage is in a first subrange, the first regulating transistor is selected to provide the output voltage and the control circuit drives the first regulating transistor to supply the output voltage while the second regulating transistor is turned off. When the target input voltage is in a second subrange, the second regulating transistor is selected to provide the output voltage and the control circuit drives the second regulating transistor to supply the output voltage while the first regulating transistor is turned off.

In this way, no single regulating transistor is responsible for providing the entire range of output voltages. Using multiple input voltages supplied to multiple regulating transistors, the worst-case efficiency of each regulating transistor is dramatically smaller than the worst-case efficiency of using a single input voltage and single regulating transistor. The voltage dropout across each transistor is substantially lower, and decreases with the addition of more input voltages, such that less energy is wasted as dissipated heat. Further, the multiple input linear voltage regulator has a reduced size and is less noisy compared to a switching regulator. Thus, the multiple input linear voltage regulator improves the efficiency and carbon footprint of the processor while ensuring that voltage demands are met.

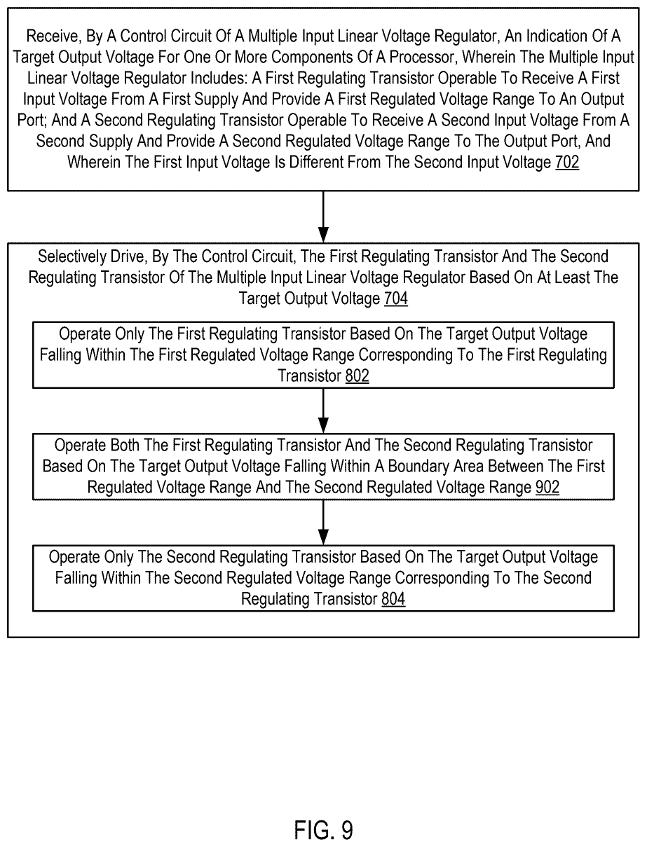

For further explanation, FIG. 9 sets forth a flow chart of another example method of a multiple input linear voltage regulator in accordance with at least one embodiment of the present disclosure. The method of FIG. 9 extends the method of FIG. 7 in that selectively operating 704 a first regulating transistor and a second regulating transistor of the multiple input linear voltage regulator based on the target output voltage includes operating 902 both the first regulating transistor and the second regulating transistor based on the target output voltage falling within a boundary area between the first range and the second range. As described above, as the target voltage approaches a crossover (e.g., equal to a Vᵢₙ voltage) from a voltage range supplied by one regulating transistor to a voltage range supplied by another regulating transistor, it is advantageous to operate both regulating transistors concurrently to avoid a disruption in the output voltage. In some examples, the control circuit operates 902 both the first regulating transistor and the second regulating transistor based on the target output voltage falling within a boundary area between the first range and the second range by turning on the second regulating transistor and increasing the pass-through voltage of the second transistor while decreasing the pass-through voltage of the first transistor. For example, this transitioning may continue while the target voltage is in the boundary area and the first transistor can be completely turned off once the target voltage has progressed beyond the boundary area. In this way, the transition from one regulating transistor to the other regulating transistor is seamless, thus ensuring that the processor will receive the proper voltage.

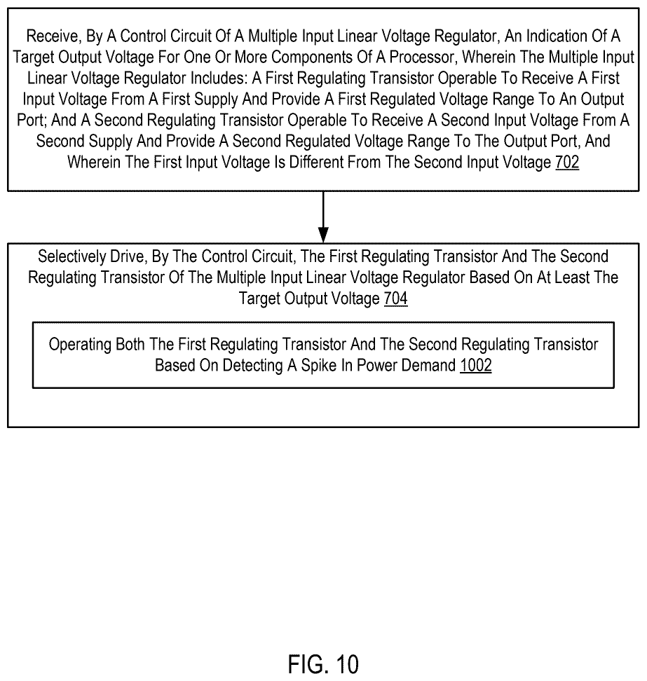

For further explanation, FIG. 10 sets forth a flow chart of another example method of a multiple input linear voltage regulator in accordance with at least one embodiment of the present disclosure. The method of FIG. 10 extends the method of FIG. 7 in that selectively operating 704 a first regulating transistor and a second regulating transistor of the multiple input linear voltage regulator based on the target output voltage includes operating 1002 both the first regulating transistor and the second regulating transistor based on detecting a spike in power demand. In some examples, the control circuit operates 1002 both the first regulating transistor and the second regulating transistor based on detecting a spike in power demand by controlling both regulating transistors to provide voltage to the output in response to detecting a peak transient condition or sudden increase in load current. For example, the control circuit can detect that the difference between the target voltage and the output voltage of the multiple input linear voltage regulator is greater than a preconfigured threshold. This indicates a sudden increase in demand that just one regulating transistor may not be able to compensate. In this case, both input voltage sources are utilized to provide the necessary current at the output. In this manner, the multiple input linear voltage regulator in accordance with the present disclosure provides the capability to handle such high load currents and peak transient conditions without disruption of the power supplied to the processor, thus ensuring proper processor function.

In view of the foregoing, it will be appreciated that embodiments in accordance with the present disclosure provide numerous advantages that contribute toward increasing power efficiency in computer processors and improving their functionality and performance. One such embodiment is directed to a multiple input linear voltage regulator that includes an output port configured to supply an output voltage to one or more processor components. The multiple input linear voltage regulator also includes a first regulating transistor operable to receive a first input voltage from a first supply and provide a first regulated voltage range to the output port. The multiple input linear voltage regulator also includes a second regulating transistor operable to receive a second input voltage from a second supply and provide a second regulated voltage range to the output port, where the first input voltage is different from the second input voltage. The multiple input linear voltage regulator further includes a control circuit operable to selectively drive the first regulating transistor and the second regulating transistor based on at least a target output voltage. In this manner, the multiple input linear voltage regulator extends the operating range at which a linear voltage regulator can remain efficient. The multiple input linear voltage regulator ensures that each regulating transistor is providing an output voltage that is never too far from one of the input voltages for optimal efficiency and minimal heat dissipation. Thus, the multiple input linear voltage regulator provides practical and sustainable linear voltage regulation to processors.

In some examples, the first regulating transistor and the second regulating transistor are field effect transistors. In some examples, the multiple input linear voltage regulator is located in one of a substrate and an interposer of a processor. In this manner, on-die space is conserved while still placing the voltage regulation close to the processor die. In other examples, the multiple input linear voltage regulator is located on a die. In this manner, tighter and more responsive control over the voltage regulation is afforded. In some variations, the control circuit receives a signal indicative of the target output voltage from a power management controller of the one or more processor components.

In some examples, the control circuit is configured to operate only the first regulating transistor based on the target output voltage falling within the first regulated voltage range corresponding to the first regulating transistor and operate only the second regulating transistor based on the target output voltage falling within the second regulated voltage range corresponding to the second regulating transistor. In this way, no single regulating transistor is responsible for providing the entire range of output voltages needed by a processor. Using multiple input voltages supplied to multiple regulating transistors, the worst-case efficiency of each regulating transistor is dramatically smaller than the worst-case efficiency of using a single input voltage and single regulating transistor. The voltage dropout across each transistor is substantially lower, and decreases with the addition of more input voltages, such that less energy is wasted as dissipated heat.

In some examples, the control circuit is configured to operate both the first regulating transistor and the second regulating transistor based on the target output voltage falling within a boundary area of the first regulated voltage range and the second regulated volage range. In this way, the transition from one regulating transistor to the other regulating transistor is seamless, thus ensuring that the processor will receive the proper voltage.

In some examples, the control circuit is configured to operate both the first regulating transistor and the second regulating transistor based on detecting a spike in power demand. In this manner, the multiple input linear voltage regulator provides the capability to handle such high load currents and peak transient conditions without disruption of the power supplied to the processor, thus ensuring proper processor function.

A variation of the above embodiment is directed to a processor that includes a plurality of processor cores and a multiple input linear voltage regulator. The multiple input linear voltage regulator includes an output port configured to supply an output voltage at least one of the plurality of processor cores. The multiple input linear voltage regulator also includes a first regulating transistor operable to receive a first input voltage from a first supply and provide a first regulated voltage range to the output port. The multiple input linear voltage regulator also includes a second regulating transistor operable to receive a second input voltage from a second supply and provide a second regulated voltage range to the output port, where the first input voltage is different from the second input voltage. The multiple input linear voltage regulator further includes a control circuit operable to selectively drive the first regulating transistor and the second regulating transistor based on at least a target output voltage. In this manner, the multiple input linear voltage regulator provides simple, compact, energy efficient, low noise voltage regulation that can be practically applied to the voltage distributions associated with computer processors.

In some examples, the first regulating transistor and the second regulating transistor are field effect transistors. In some examples, the multiple input linear voltage regulator is located in one of a substrate and an interposer of a processor. In this manner, on-die space is conserved while still placing the voltage regulation close to the processor die. In other examples, the multiple input linear voltage regulator is located on a die. In this manner, tighter and more responsive control over the voltage regulation is afforded. In some variations, the control circuit receives a signal indicative of the target output voltage from a power management controller of the one or more processor components.

In some examples, the multiple input linear voltage regulator is one of a plurality of multiple input linear voltage regulators, where each of the plurality of multiple input linear voltage regulators provides an output voltage to a respective one of the plurality of processor cores. In this way, each core can have its own voltage domain that is independent of the other cores. Thus, an idle core does not need to receive the same voltage as a core executing a heavy workload. In some examples, the control circuit receives a signal indicative of the target output voltage from a power management controller of one or more of the plurality of processor cores. As each core signals its power demand to the control circuit of the multiple input linear voltage regulator, the core can receive a voltage that is appropriate to the conditions in that specific core. In some examples, the control circuit is configured to turn a core off via a respective multiple input linear voltage regulator.

In some examples, the control circuit is configured to operate only the first regulating transistor based on the target output voltage falling within the first regulated voltage range corresponding to the first regulating transistor and operate only the second regulating transistor based on the target output voltage falling within the second regulated voltage range corresponding to the second regulating transistor. In this way, no single regulating transistor is responsible for providing the entire range of output voltages. Using multiple input voltages supplied to multiple regulating transistors, the worst-case efficiency of each regulating transistor is dramatically smaller than the worst-case efficiency of using a single input voltage and single regulating transistor. The voltage dropout across each transistor is substantially lower, and decreases with the addition of more input voltages, such that less energy is wasted as dissipated heat.

In some examples, the control circuit is configured to operate both the first regulating transistor and the second regulating transistor based on the target output voltage falling within a boundary area of the first regulated voltage range and the second regulated voltage range. In this way, the transition from one regulating transistor to the other regulating transistor is seamless, thus ensuring that the processor will receive the proper voltage.

Another variation of the above embodiment is a method for a multiple input linear voltage regulator. The method includes receiving, by a control circuit of a multiple input linear voltage regulator, an indication of a target output voltage for one or more components of a processor. The multiple input linear voltage regulator includes a first regulating transistor operable to receive a first input voltage from a first supply and provide a first regulated voltage range to an output port. The multiple input linear voltage regulator also includes a second regulating transistor operable to receive a second input voltage from a second supply and provide a second regulated voltage range to the output port, where the first input voltage is different from the second input voltage. The method also includes selectively driving, by the control circuit, the first regulating transistor and the second regulating transistor of the multiple input linear voltage regulator based on at least the target output voltage. In this manner, a multiple input linear voltage regulator extends the operating range at which a linear voltage regulator can remain efficient. Thus, the multiple input linear voltage regulator in accordance with the present disclose provides practical and sustainable linear voltage regulation to processors. Because of its compact size compared to switching regulators, the design of the multiple input linear voltage regulator is amenable to providing a unique voltage domain at every core of the chip. Further, because of its case of implementation, design and fabrication costs are reduced.

In some examples, selectively driving, by the control circuit, the first regulating transistor and the second regulating transistor of the multiple input linear voltage regulator based on the target output voltage includes operating only the first regulating transistor based on the target output voltage falling within the first regulated voltage range corresponding to the first regulating transistor and operating only the second regulating transistor based on the target output voltage falling within the second regulated voltage range corresponding to the second regulating transistor. In this way, no single regulating transistor is responsible for providing the entire range of output voltages needed by a processor. Using multiple input voltages supplied to multiple regulating transistors, the worst-case efficiency of each regulating transistor is dramatically smaller than the worst-case efficiency of using a single input voltage and single regulating transistor. The voltage dropout across each transistor is substantially lower, and decreases with the addition of more input voltages, such that less energy is wasted as dissipated heat.

In some examples, selectively driving, by the control circuit, the first regulating transistor and the second regulating transistor of the multiple input linear voltage regulator based on the target output voltage includes operating both the first regulating transistor and the second regulating transistor based on the target output voltage falling within a boundary area between the first regulated range and the second regulated range. In this way, the transition from one regulating transistor to the other regulating transistor is seamless, thus ensuring that the processor will receive the proper voltage.

In some examples, selectively driving, by the control circuit, the first regulating transistor and the second regulating transistor of the multiple input linear voltage regulator based on the target output voltage includes operating both the first regulating transistor and the second regulating transistor based on detecting a spike in power demand. In this manner, the multiple input linear voltage regulator in accordance with the present disclosure provides the capability to handle such high load currents and peak transient conditions without disruption of the power supplied to the processor, thus ensuring proper processor function.

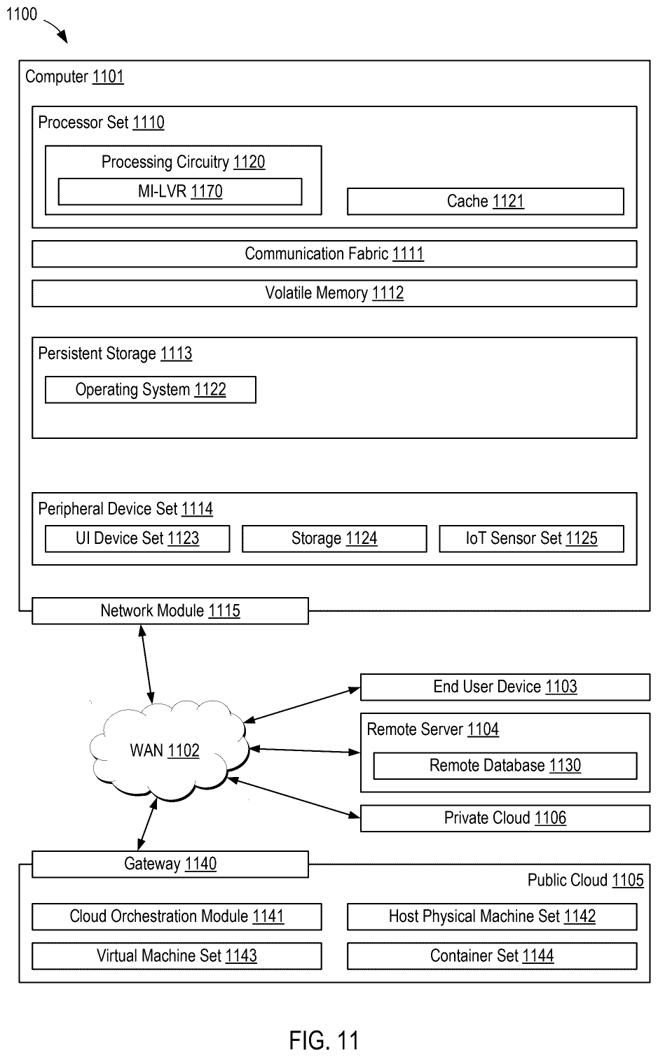

FIG. 11 sets forth an example computing environment according to aspects of the present disclosure. Computing environment includes, for example, computer 1101, wide area network (WAN) 1102, end user device (EUD) 1103, remote server 1104, public cloud 1105, and private cloud 1106. In this embodiment, computer 1101 includes processor set 1110 (including processing circuitry 1120 and cache 1121), communication fabric 1111, volatile memory 1112, persistent storage 1113 (including operating system 1122, as identified above), peripheral device set 1114 (including user interface (UI) device set 1123, storage 1124, and Internet of Things (IoT) sensor set 1125), and network module 1115. Remote server 1104 includes remote database 1130. Public cloud 1105 includes gateway 1140, cloud orchestration module 1141, host physical machine set 1142, virtual machine set 1143, and container set 1144.

Computer 1101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 1130. As is well understood in the art of computer technology, and depending upon the technology, performance of a computer-implemented method may be distributed among multiple computers and/or between multiple locations. On the other hand, in this presentation of computing environment 1100, detailed discussion is focused on a single computer, specifically computer 1101, to keep the presentation as simple as possible. Computer 1101 may be located in a cloud, even though it is not shown in a cloud in FIG. 11. On the other hand, computer 1101 is not required to be in a cloud except to any extent as may be affirmatively indicated.

Processor set 1110 includes one, or more, computer processors of any type now known or to be developed in the future. Processing circuitry 1120 may be distributed over multiple packages, for example, multiple, coordinated integrated circuit chips. Processing circuitry 1120 may implement multiple processor threads and/or multiple processor cores. Cache 1121 is memory that is located in the processor chip package(s) and is typically used for data or code that should be available for rapid access by the threads or cores running on processor set 1110. Cache memories are typically organized into multiple levels depending upon relative proximity to the processing circuitry. Alternatively, some, or all, of the cache for the processor set may be located “off chip.” In some computing environments, processor set 1110 may be designed for working with qubits and performing quantum computing. One or more integrated circuit chips or processors of the processing circuitry includes one or more multiple input linear voltage regulators 1170, such as those discussed previously.

Computer readable program instructions are typically loaded onto computer 1101 to cause a series of operational steps to be performed by processor set 1110 of computer 1101 and thereby effect a computer-implemented method, such that the instructions thus executed will instantiate the methods specified in flowcharts and/or narrative descriptions of computer-implemented methods included in this document. These computer readable program instructions are stored in various types of computer readable storage media, such as cache 1121 and the other storage media discussed below. The program instructions, and associated data, are accessed by processor set 1110 to control and direct performance of the computer-implemented methods. In computing environment 1100, at least some of the instructions for performing computer-implemented methods may be stored in persistent storage 1113.

Communication fabric 1111 is the signal conduction path that allows the various components of computer 1101 to communicate with each other. Typically, this fabric is made of switches and electrically conductive paths, such as the switches and electrically conductive paths that make up buses, bridges, physical input/output ports and the like. Other types of signal communication paths may be used, such as fiber optic communication paths and/or wireless communication paths.

Volatile memory 1112 is any type of volatile memory now known or to be developed in the future. Examples include dynamic type random access memory (RAM) or static type RAM. Typically, volatile memory 1112 is characterized by random access, but this is not required unless affirmatively indicated. In computer 1101, the volatile memory 1112 is located in a single package and is internal to computer 1101, but, alternatively or additionally, the volatile memory may be distributed over multiple packages and/or located externally with respect to computer 1101.

Persistent storage 1113 is any form of non-volatile storage for computers that is now known or to be developed in the future. The non-volatility of this storage means that the stored data is maintained regardless of whether power is being supplied to computer 1101 and/or directly to persistent storage 1113. Persistent storage 1113 may be a read only memory (ROM), but typically at least a portion of the persistent storage allows writing of data, deletion of data and re-writing of data. Some familiar forms of persistent storage include magnetic disks and solid state storage devices. Operating system 1122 may take several forms, such as various known proprietary operating systems or open source Portable Operating System Interface-type operating systems that employ a kernel.

Peripheral device set 1114 includes the set of peripheral devices of computer 1101. Data communication connections between the peripheral devices and the other components of computer 1101 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 1123 may include components such as a display screen, speaker, microphone, wearable devices (such as goggles and smart watches), keyboard, mouse, printer, touchpad, game controllers, and haptic devices. Storage 1124 is external storage, such as an external hard drive, or insertable storage, such as an SD card. Storage 1124 may be persistent and/or volatile. In some embodiments, storage 1124 may take the form of a quantum computing storage device for storing data in the form of qubits. In embodiments where computer 1101 is required to have a large amount of storage (for example, where computer 1101 locally stores and manages a large database), this storage may be provided by peripheral storage devices designed for storing very large amounts of data, such as a storage area network (SAN) that is shared by multiple, geographically distributed computers. IoT sensor set 1125 is made up of sensors that can be used in Internet of Things applications. For example, one sensor may be a thermometer and another sensor may be a motion detector.

Network module 1115 is the collection of computer software, hardware, and firmware that allows computer 1101 to communicate with other computers through WAN 1102. Network module 1115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 1115 are performed on the same physical hardware device. In other embodiments (for example, embodiments that utilize software-defined networking (SDN)), the control functions and the forwarding functions of network module 1115 are performed on physically separate devices, such that the control functions manage several different network hardware devices. Computer readable program instructions for performing the computer-implemented methods can typically be downloaded to computer 1101 from an external computer or external storage device through a network adapter card or network interface included in network module 1115.

WAN 1102 is any wide area network (for example, the internet) capable of communicating computer data over non-local distances by any technology for communicating computer data, now known or to be developed in the future. In some embodiments, the WAN 1102 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

End user device (EUD) 1103 is any computer system that is used and controlled by an end user (for example, a customer of an enterprise that operates computer 1101), and may take any of the forms discussed above in connection with computer 1101. EUD 1103 typically receives helpful and useful data from the operations of computer 1101. For example, in a hypothetical case where computer 1101 is designed to provide a recommendation to an end user, this recommendation would typically be communicated from network module 1115 of computer 1101 through WAN 1102 to EUD 1103. In this way, EUD 1103 can display, or otherwise present, the recommendation to an end user. In some embodiments, EUD 1103 may be a client device, such as thin client, heavy client, mainframe computer, desktop computer and so on.

Remote server 1104 is any computer system that serves at least some data and/or functionality to computer 1101. Remote server 1104 may be controlled and used by the same entity that operates computer 1101. Remote server 1104 represents the machine(s) that collect and store helpful and useful data for use by other computers, such as computer 1101. For example, in a hypothetical case where computer 1101 is designed and programmed to provide a recommendation based on historical data, then this historical data may be provided to computer 1101 from remote database 1130 of remote server 1104.

Public cloud 1105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economics of scale. The direct and active management of the computing resources of public cloud 1105 is performed by the computer hardware and/or software of cloud orchestration module 1141. The computing resources provided by public cloud 1105 are typically implemented by virtual computing environments that run on various computers making up the computers of host physical machine set 1142, which is the universe of physical computers in and/or available to public cloud 1105. The virtual computing environments (VCEs) typically take the form of virtual machines from virtual machine set 1143 and/or containers from container set 1144. It is understood that these VCEs may be stored as images and may be transferred among and between the various physical machine hosts, either as images or after instantiation of the VCE. Cloud orchestration module 1141 manages the transfer and storage of images, deploys new instantiations of VCEs and manages active instantiations of VCE deployments. Gateway 1140 is the collection of computer software, hardware, and firmware that allows public cloud 1105 to communicate through WAN 1102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

Private cloud 1106 is similar to public cloud 1105, except that the computing resources are only available for use by a single enterprise. While private cloud 1106 is depicted as being in communication with WAN 1102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 1105 and private cloud 1106 are both part of a larger hybrid cloud.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A multiple input linear voltage regulator comprising:
an output port configured to supply an output voltage to one or more processor components;
a first regulating transistor operable to receive a first input voltage from a first supply and provide a first regulated voltage range to the output port;
a second regulating transistor operable to receive a second input voltage from a second supply and provide a second regulated voltage range to the output port, wherein the first input voltage is different from the second input voltage; and
a control circuit operable to selectively drive the first regulating transistor and the second regulating transistor based on at least a target output voltage.

2. The multiple input linear voltage regulator of claim 1, wherein the control circuit receives a signal indicative of the target output voltage from a power management controller of the one or more processor components.

3. The multiple input linear voltage regulator of claim 1, wherein the control circuit is configured to:
operate only the first regulating transistor based on the target output voltage falling within the first regulated voltage range corresponding to the first regulating transistor; and
operate only the second regulating transistor based on the target output voltage falling within the second regulated voltage range corresponding to the second regulating transistor.

4. The multiple input linear voltage regulator of claim 3, wherein the control circuit is configured to:
operate both the first regulating transistor and the second regulating transistor based on the target output voltage falling within a boundary area of the first regulated voltage range and the second regulated voltage range.

5. The multiple input linear voltage regulator of claim 1, wherein the control circuit is configured to:
operate both the first regulating transistor and the second regulating transistor based on detecting a spike in power demand.

6. The multiple input linear voltage regulator of claim 1, wherein the first regulating transistor and the second regulating transistor are field effect transistors.

7. The multiple input linear voltage regulator of claim 1, wherein the multiple input linear voltage regulator is located in one of a substrate and an interposer of a processor.

8. The multiple input linear voltage regulator of claim 1, wherein the multiple input linear voltage regulator is located on a die.

9. A processor comprising:
a plurality of processor cores; and
a multiple input linear voltage regulator, the multiple input linear voltage regulator including:
an output port configured to supply an output voltage at least one of the plurality of processor cores;
a first regulating transistor operable to receive a first input voltage from a first supply and provide a first regulated voltage range to the output port;
a second regulating transistor operable to receive a second input voltage from a second supply and provide a second regulated voltage range to the output port, wherein the first input voltage is different from the second input voltage; and
a control circuit operable to selectively drive the first regulating transistor and the second regulating transistor based on at least a target output voltage.

10. The processor of claim 9, wherein the multiple input linear voltage regulator is one of a plurality of multiple input linear voltage regulators, and wherein each of the plurality of multiple input linear voltage regulators provides an output voltage to a respective one of the plurality of processor cores.

11. The processor of claim 10, wherein the control circuit receives a signal indicative of the target output voltage from a power management controller of one or more of the plurality of processor cores.

12. The processor of claim 10, wherein the control circuit is configured to turn a core off via a respective multiple input linear voltage regulator.

13. The processor of claim 9, wherein the control circuit is configured to:
operate only the first regulating transistor based on the target output voltage falling within the first regulated voltage range corresponding to the first regulating transistor; and
operate only the second regulating transistor based on the target output voltage falling within the second regulated voltage range corresponding to the second regulating transistor.

14. The processor of claim 13, wherein the control circuit is configured to:
operate both the first regulating transistor and the second regulating transistor based on the target output voltage falling within a boundary area of the first regulated range and the second regulated voltage range.

15. The processor of claim 9, wherein the multiple input linear voltage regulator is located in one of a substrate and an interposer of the processor.

16. The processor of claim 9, wherein the multiple input linear voltage regulator is located on a die of the processor.

17. A method comprising:
receiving, by a control circuit of a multiple input linear voltage regulator, an indication of a target output voltage for one or more components of a processor, wherein the multiple input linear voltage regulator includes:
a first regulating transistor operable to receive a first input voltage from a first supply and provide a first regulated voltage range to an output port; and
a second regulating transistor operable to receive a second input voltage from a second supply and provide a second regulated voltage range to the output port, and wherein the first input voltage is different from the second input voltage; and
selectively driving, by the control circuit, the first regulating transistor and the second regulating transistor of the multiple input linear voltage regulator based on at least the target output voltage.

18. The method of claim 17, wherein selectively driving, by the control circuit, the first regulating transistor and the second regulating transistor of the multiple input linear voltage regulator based on the target output voltage includes:
operating only the first regulating transistor based on the target output voltage falling within the first regulated voltage range corresponding to the first regulating transistor; and
operating only the second regulating transistor based on the target output voltage falling within the second regulated voltage range corresponding to the second regulating transistor.

19. The method of claim 18, wherein selectively driving, by the control circuit, the first regulating transistor and the second regulating transistor of the multiple input linear voltage regulator based on the target output voltage includes:
operating both the first regulating transistor and the second regulating transistor based on the target output voltage falling within a boundary area between the first regulated voltage range and the second regulated voltage range.

20. The method of claim 17, wherein selectively driving, by the control circuit, the first regulating transistor and the second regulating transistor of the multiple input linear voltage regulator based on the target output voltage includes:
operating both the first regulating transistor and the second regulating transistor based on detecting a spike in power demand.
